(19) United States
(12) Patent Application Publication
(10) Pub. No.: US 2025/0054784 A1
(43) Pub. Date: Feb. 13, 2025

(54) TEMPERATURE CONTROL DEVICE AND WAFER PROCESSING SYSTEM

(71) Applicant: KELK Ltd., Hiratsuka-shi (JP)

(72) Inventors: Atsushi Kobayashi, Hiratsuka-shi (JP); Wataru Omuro, Hiratsuka-shi (JP)

(73) Assignee: KELK Ltd., Hiratsuka-shi (JP)

(21) Appl. No.: 18/793,004

(22) Filed: Aug. 2, 2024

(30) Foreign Application Priority Data
Aug. 9, 2023 (JP) 2023-130189

(51) Int. Cl. H01L 21/67; H01L 21/683; H01L 21/687; H10N 10/10

(52) U.S. Cl. CPC H01L 21/67103; H01L 21/6838; H01L 21/68757; H01L 21/68785; H10N 10/10

(57) ABSTRACT

A temperature control device of the present invention includes: a top plate which is formed in a disk shape centered on an axis and has a placement surface for placing an object thereon; a Peltier member that is disposed in contact with the top plate from the direction of the axis; a cooling plate which is disposed on the Peltier member on the side opposite to the top plate in the direction of the axis to come into contact with the Peltier member and allows a refrigerant to flow therein; a cover plate which forms an accommodation space accommodating the Peltier member and the cooling plate between the top plate and the cover plate; and a pressure reducing device which reduces the pressure within the accommodation space, wherein the top plate and the cooling plate are not in contact with each other.

### BACKGROUND OF THE INVENTION

### Field of the Invention

The present invention relates to a temperature control device and a wafer processing system. Priority is claimed on Japanese Patent Application No. 2023-130189, filed Aug. 9, 2023, the content of which is incorporated herein by reference.

### Description of Related Art

In a semiconductor manufacturing apparatus, a temperature control device that controls the temperature of a wafer is used. As a specific example of this type of apparatus, a semiconductor manufacturing apparatus disclosed in Japanese Patent Application Laid-Open No. 2022-18881 is known. The semiconductor manufacturing apparatus disclosed in Japanese Patent Application Laid-Open No. 2022-18881 mainly includes a circular top plate, a plurality of Peltier modules which are stacked under the top plate, and a cooling plate which supports these Peltier modules from below and controls the temperature. A refrigerant flows inside the cooling plate. An airtight space is formed between the cooling plate and the top plate, and the Peltier module is accommodated within the space.

Here, the temperature control device described above may be used within a vacuum chamber. In that case, the pressure in the space housing the above-described Peltier module becomes relatively high compared to the surrounding pressure, and the top plate deforms due to the pressure difference. Therefore, the device is configured to suck the air in the space so that the pressure difference with the surroundings becomes small.

By the way, the cooling plate itself may deform due to the heat of the Peltier module and the pressure difference. Therefore, when a space is formed by coupling the top plate and the cooling plate as described above, the top plate may still be affected and deformed or distorted.

### SUMMARY OF THE INVENTION

The present invention has been made to solve the above-described problems and an object thereof is to provide a temperature control device and a wafer processing system in which deformation of a top plate is further suppressed.

In order to solve the above-described problems, a temperature control device according to the present invention includes: a top plate which is formed in a disk shape centered on an axis and has a placement surface for placing an object thereon; a Peltier member that is disposed in contact with the top plate from the direction of the axis; a cooling plate which is disposed on the Peltier member on the side opposite to the top plate in the direction of the axis to come into contact with the Peltier member and allows a refrigerant to flow therein; a cover plate which forms an accommodation space accommodating the Peltier member and the cooling plate between the top plate and the cover plate; and a pressure reducing device which reduces the pressure within the accommodation space, wherein the top plate and the cooling plate are not in contact with each other.

A wafer processing system according to the present invention includes the temperature control device and a chamber having a low pressure space accommodating the temperature control device.

According to the present invention, it is possible to provide the temperature control device and the wafer processing system in which the deformation of the top plate is further suppressed.

### BRIEF DESCRIPTION OF THE DRAWINGS

FIG. 1 is an overall diagram showing a configuration of a wafer processing system according to an embodiment of the present invention.

FIG. 2 is a cross-sectional view showing a configuration of a temperature control device according to the embodiment of the present invention.

FIG. 3 is an enlarged cross-sectional view of a main part showing a modified example of the temperature control device according to the embodiment of the present invention.

### DETAILED DESCRIPTION OF THE INVENTION

### Configuration of Wafer Processing System 1

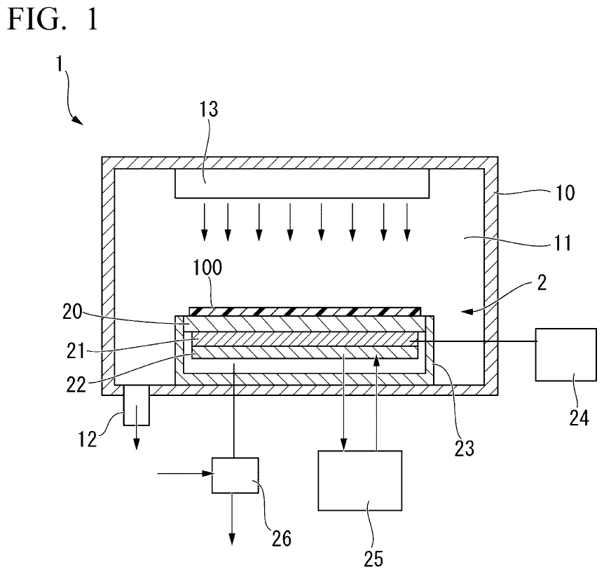

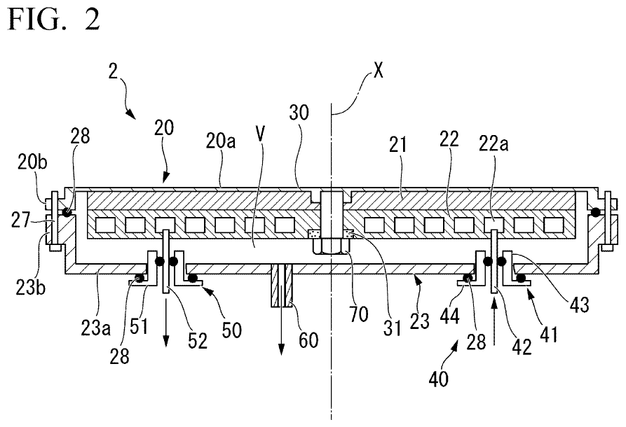

Hereinafter, a wafer processing system 1 and a temperature control device 2 according to an embodiment of the present invention will be described with reference to FIGS. 1 and 2.

The wafer processing system 1 is an apparatus that supports a silicon wafer (wafer 100) used in semiconductor manufacturing as an object and performs various processes on the wafer 100. As shown in FIG. 1, the wafer processing system 1 includes a chamber 10 and the temperature control device 2.

The chamber 10 is a housing with a space formed therein, and the inside is evacuated to form a low pressure space 11. The pressure in this low pressure space 11 is preferably 1 Pa or more and 250 Pa or less. More preferably, the pressure in the low pressure space 11 is 1.5 Pa or more and 230 Pa or less. Most preferably, the pressure in the low pressure space 11 is 2 Pa or more and 220 Pa or less.

The chamber 10 is provided with an exhaust pipe 12 for discharging air to the outside. Through this exhaust pipe 12, the air in the low pressure space 11 is sucked to the outside, and the above-described pressure state is realized. Furthermore, the pressure may not necessarily need to be reduced and the pressure in the chamber 10 may be equivalent to atmospheric pressure depending on the type of process performed on the wafer 100. A gas supply device 13 is disposed on the top surface (inner surface opposing downward) of the chamber 10. This gas supply device 13 supplies a gas containing a rare gas element such as argon or xenon into the chamber 10.

### Configuration of Temperature Control Device 2

The temperature control device 2 is disposed on the bottom surface of the chamber 10. The temperature control device 2 is a device that controls the temperature of the wafer 100. The temperature control device 2 includes a top plate 20, a Peltier member 21, a cooling plate 22, a cover plate 23, a power supply device 24, a cooling water supply device 25, and a vacuum generator 26 (pressure reducing device).

The top plate 20 has a placement surface 30 on which the wafer 100 is placed. The placement surface 30 is a surface opposing upward. As shown in FIG. 2, the top plate 20 has a disk shape centered on the axis X. Again, as shown in FIG. 1, the Peltier member 21 is provided below the top plate 20. The Peltier member 21 is connected to the power supply device 24. The Peltier member 21 is an assembly of circuit elements (Peltier elements) that can generate or absorb heat when supplied with current from the power supply device 24. The cooling plate 22 is provided further below the Peltier member 21. That is, the cooling plate 22 is provided on the opposite side of the top plate 20 with respect to the Peltier member 21. The cooling plate 22 is a member for more precisely controlling the temperature of the Peltier member 21. A flow path 22a through which cooling water (refrigerant) supplied and discharged from the cooling water supply device 25 flows is formed in the cooling plate 22 (see FIG. 2).

The Peltier member 21 and the cooling plate 22 are accommodated in the accommodation space V formed by the top plate 20 and the cover plate 23. In other words, the cover plate 23 covers the Peltier member 21 and the cooling plate 22 from below. As will be described in detail later, the cover plate 23 is coupled to the top plate 20 and maintains the airtight state of the accommodation space V. The vacuum generator 26 is provided to reduce the pressure within this accommodation space V. The vacuum generator 26 is, for example, an ejector, and guides the air in the accommodation space V to the outside along with the flow of the air by receiving air from the outside. Accordingly, the pressure in the accommodation space Vis reduced. As an example, the pressure in the accommodation space V is preferably 3 kPa or more and 30 kPa or less. More preferably, this pressure is 5 kPa or more and 27 kPa or less. Most preferably, this pressure is 7 kPa or more and 25 kPa or less.

Next, the detailed configuration of the temperature control device 2 will be described with reference to FIG. 2. As shown in the same figure, the top plate 20 includes a disk-shaped plate main body 20a and a flange portion 20b projecting toward the outer peripheral side of the plate main body 20a. The cover plate 23 includes a cover plate main body 23a that forms the lower part of the accommodation space V and a opposing flange portion 23b that projects outward from the cover plate main body 23a.

The flange portion 20b is fastened and fixed by bolts 27 while opposing the opposing flange portion 23b from the direction of the axis X. Further, an O-ring serving as a seal member 28 is sandwiched between the flange portion 20b and the opposing flange portion 23b. Accordingly, airtightness between accommodation space V and the outside is ensured. Further, since the cover plate 23 is provided, the top plate 20 and the cooling plate 22 do not come into contact with each other when forming the accommodation space V.

Further, the top plate 20 and the cover plate 23 are fastened to each other at the position of the axis X by a center bolt (bolt) 70. The center bolt 70 is screwed into the top plate 20 from the side of the cover plate 23. A heat insulating member 31 is provided at a portion of the cover plate 23 that is in contact with the center bolt 70. As the heat insulating member 31, resin such as rubber or a porous body is suitably used.

Furthermore, the cover plate 23 is provided with a supply section 40 and a discharge section 50 for supplying and discharging cooling water to the flow path 22a of the cooling plate 22. The supply section 40 includes a cylindrical first bracket 41 that is inserted into an opening provided at the bottom of the cover plate 23, a supply pipe 42 that is supported by the cylindrical first bracket 41, and the seal member 28 that fills gaps between each part. The first bracket 41 includes a cylindrical main body portion 43 and an overhang portion 44 which projects from one end of the main body portion 43 toward the outer peripheral side. The overhang portion 44 is exposed to the outside of the cover plate 23. The seal member 28 is provided between the supply pipe 42 and the bracket and between the bracket (overhang portion 44) and the bottom surface of the cover plate 23. In this way, the discharge section 50 includes a second bracket 51, a discharge pipe 52, and the seal member 28. The position where the seal member 28 is provided is the same as that of the supply section 40. In addition, an exhaust flow path 60 connected to the vacuum generator 26 is provided below the cover plate 23.

When using the temperature control device 2, first, cooling water is supplied and drained to the cooling plate 22, and current is supplied to the Peltier member 21 for heating or cooling. In this state, the wafer 100 is placed on the placement surface 30 of the top plate 20 and various processes such as cleaning, etching, and vapor deposition are performed on the wafer 100. At this time, it is possible to maintain the temperature of the wafer 100 to be uniform and constant by the temperature control device 2.

By the way, the cooling plate 22 may deform itself based on the heat of the Peltier module or the pressure difference between the surroundings and the accommodation space V. Therefore, when the accommodation space V is formed by combining the top plate 20 and the cooling plate 22 as in the past, the top plate 20 may still be affected and deformed or distorted. As a result, the flatness of the top plate 20 is impaired, which affects the processing of the wafer 100. Therefore, in this embodiment, each of the above-described configurations is adopted.

### Effect

The temperature control device 2 of the above-described embodiment can exhibit the following effects

In this embodiment, the top plate 20 and the cover plate 23 are coupled to form the accommodation space V therein and the top plate 20 and the cooling plate 22 are not in contact with each other.

Accordingly, even if the cooling plate 22 is deformed due to heat or pressure difference, the stress due to the deformation does not reach the top plate 20. Therefore, the possibility of deformation or distortion occurring in the top plate 20 is reduced, and high flatness can be maintained.

In this embodiment, the seal member 28 that ensures airtightness between the top plate 20 and the cover plate 23 is further provided.

Accordingly, airtightness within the accommodation space V formed by the top plate 20 and the cover plate 23 can be ensured. Therefore, the pressure in the accommodation space V can be stably reduced by the pressure reducing device.

In this embodiment, the top plate 20 includes the Peltier member 21 and the flange portion 20b which projects toward the outer peripheral side of the cooling plate 22 when viewed from the direction of the axis X and the cover plate 23 includes the opposing flange portion 23b which opposes the flange portion 20b and sandwiches the seal member 28.

Since the top plate 20 and the cover plate 23 are coupled by the flange portion 20b and the opposing flange portion 23b, the area of the placement surface 30 of the top plate 20 is not eroded. Further, it is possible to easily and stably ensure an airtight state in the accommodation space V only by fastening these flange portions 20b and opposing flange portions 23b with bolts 27 or the like. Accordingly, the manufacturing cost and maintenance cost of the device can be significantly reduced.

In this embodiment, the center bolt 70 which fastens the top plate 20 and the cooling plate 22 from the direction of the axis X and the heat insulating member 31 that is disposed at a portion of the cooling plate 22 that is in contact with the center bolt 70 are further provided.

The top plate 20 and the cooling plate 22 need to be fastened and fixed from both sides in the thickness direction (the direction of the axis X) in order to sandwich the Peltier member 21 therebetween. Therefore, the center bolt 70 is used. However, if the top plate 20 and the cooling plate 22 are thermally connected by the center bolt 70, heat will be exchanged therebetween, and the uniformity of the temperature of the top plate 20 will be impaired. Thus, as described above, the heat insulating member 31 is provided at a portion of the cooling plate 22 that is in contact with the center bolt 70. Accordingly, the center bolt 70 and the cooling plate 22 are thermally insulated, and the above-described exchange of heat does not occur. Therefore, it is possible to further improve the uniformity of the temperature of the top plate 20.

In this embodiment, the dimension of the top plate 20 in the direction of the axis X is 0.1 mm or more and 5 mm or less.

As described above, since the pressure in the accommodation space V is reduced and the pressure difference with the surroundings is reduced, the top plate 20 is less likely to be deformed due to the pressure difference. Therefore, the thickness of the top plate 20 (the dimension in the direction of the axis X) can be kept within a small range of 0.1 mm or more and 5 mm or less. As a result, since the responsiveness of temperature control due to the transfer of heat from the Peltier member 21 to the top plate 20 becomes high, it is possible to proceed with various production processes more efficiently and stably.

In this embodiment, at least one of the top plate 20 and the cover plate 23 is made of one material selected from the group consisting of aluminum, aluminum alloy, stainless steel, copper, copper alloy, and ceramics.

Accordingly, the rigidity, heat transfer performance, and manufacturing cost of the top plate 20 and the cover plate 23 can all be ensured at a high level. Therefore, it is possible to achieve a high level of balance between the performance and cost of the temperature control device 2.

Although the embodiment of the present invention has been described above in detail with reference to the drawings, the specific configuration is not limited to this embodiment and may include design changes without departing from the gist of the present invention.

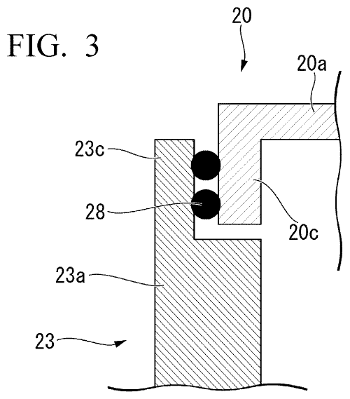

For example, as shown in FIG. 3 as a modified example, the top plate 20 may include a cylindrical portion 20c which covers the Peltier member 21 and the cooling plate 22 from the outer peripheral side and has a cylindrical shape centered on the axis X and the cover plate 23 may include a cylindrical opposing cylindrical portion 23c which opposes the cylindrical portion 20c from the radial direction and sandwiches the seal member 28.

According to this configuration, the same effect (sealing effect) as the above-described configuration can be obtained. In addition, since the cylindrical portion 20c and the opposing cylindrical portion 23c oppose each other from the radial direction and sandwich the seal member 28, the cylindrical portion 20c is strongly pressed against the opposing cylindrical portion 23c, for example, even if the top plate 20 undergoes thermal expansion in the radial direction. Therefore, further airtightness can be ensured. On the other hand, it is possible to absorb thermal expansion and deformation of the top plate 20 due to the deformation of the seal member 28 by adjusting the dimensions and hardness of the seal member 28. Accordingly, the performance of the temperature control device 2 can be further improved.

Further, in the above-described embodiment, an example in which the Peltier member 21 has a uniform disk shape has been described, but the shape of the Peltier member 21 is not limited thereto. As another example, it is also possible to adopt a configuration in which a plurality of Peltier elements are arranged at intervals on a plane. However, a uniform disk-shaped structure is more advantageous in that temperature unevenness of the top plate 20 is less likely to occur.

Furthermore, the temperature control device 2 can be used for various work processes even if the temperature control device is not inside the chamber 10 described above. Even in this case, the same effects as those described above can be obtained.

Moreover, the number of seal members 28 in each part described above is an example, and can be changed as appropriate according to the design and specifications. In either case, the same effects as those described above can be obtained.

### EXPLANATION OF REFERENCES

1 Wafer processing system
2 Temperature control device
10 Chamber
11 Low pressure space
12 Exhaust pipe
13 Gas supply device
20 Top plate
20a Plate main body
20b Flange portion
20c Cylindrical portion
21 Peltier member
22 Cooling plate
22a Flow path
23 Cover plate
23a Cover plate main body
23b Opposing flange portion
23c Opposing cylindrical portion
24 Power supply device
25 Cooling water supply device
26 Vacuum generator
27 Bolt
28 Seal member
30 Placement surface
31 Heat insulating member
40 Supply section
41 First bracket
42 Supply pipe
43 Main body portion
44 Overhang portion
50 Discharge section
51 Second bracket
52 Discharge pipe
60 Exhaust flow path
70 Center bolt
100 Wafer
X Axis
V Accommodation space

What is claimed is:

1. A temperature control device comprising:
a top plate which is formed in a disk shape centered on an axis and has a placement surface for placing an object thereon;
a Peltier member that is disposed in contact with the top plate from a direction of the axis;
a cooling plate which is disposed on the Peltier member on the side opposite to the top plate in the direction of the axis to come into contact with the Peltier member and allows a refrigerant to flow therein;
a cover plate which forms an accommodation space accommodating the Peltier member and the cooling plate between the top plate and the cover plate; and
a pressure reducing device which reduces the pressure within the accommodation space,
wherein the top plate and the cooling plate are not in contact with each other.

2. The temperature control device according to claim 1, further comprising:
a seal member that ensures airtightness between the top plate and the cover plate.

3. The temperature control device according to claim 2,
wherein the top plate includes a flange portion which projects toward the outer peripheral side of the Peltier member and the cooling plate when viewed from the direction of the axis, and
wherein the cover plate includes an opposing flange portion which opposes the flange portion and sandwiches the seal member.

4. The temperature control device according to claim 2,
wherein the top plate includes a cylindrical portion which covers the Peltier member and the cooling plate from the outer peripheral side and has a cylindrical shape centered on the axis, and
wherein the cover plate includes a cylindrical opposing cylindrical portion which opposes the cylindrical portion from a radial direction and sandwiches the seal member.

5. The temperature control device according to claim 1, further comprising:
a bolt which fastens the top plate and the cooling plate from the direction of the axis; and
a heat insulating member that is disposed in a portion contacting the bolt in the cooling plate.

6. The temperature control device according to claim 1,
wherein the top plate has a dimension of 0.1 mm or more and 5 mm or less in the direction of the axis.

7. The temperature control device according to claim 1,
wherein at least one of the top plate and the cover plate is made of one material selected from the group consisting of aluminum, aluminum alloy, stainless steel, copper, copper alloy, and ceramics.

8. A wafer processing system comprising:
the temperature control device according to claim 1; and
a chamber which has a low pressure space accommodating the temperature control device.

9. The wafer processing system according to claim 8,
wherein the low pressure space has a pressure of 1 Pa or more and 250 Pa or less and the accommodation space has a pressure of 0.3 kPa or more and 30 kPa or less.
